(19) United States
(12) Patent Application Publication
(10) Pub. No.: US 2008/0265815 A1
(43) Pub. Date: Oct. 30, 2008

(54) HARMONIC PROCESSOR

(75) Inventor: Bruno Nadd, Lourmain (FR)

Correspondence Address: OSTROLENK FABER GERB & SOFFEN, 1180 AVENUE OF THE AMERICAS, NEW YORK, NY, 100368403, US

(73) Assignee: INTERNATIONAL RECTIFIER CORPORATION, El Segundo, CA (US)

(21) Appl. No.: 12/107,864

(22) Filed: Apr. 23, 2008

Related U.S. Application Data
(60) Provisional application No. 60/913,922, filed on Apr. 25, 2007.

(51) Int. Cl. H02P 21/00; H03K 17/00

(52) U.S. Cl. 318/400.02; 327/98

(57) ABSTRACT

A harmonic processor receiving an input signal and providing an output signal, the input signal comprising a first analog signal having amplitude, frequency and phase components and being converted to an instantaneous magnitude output signal, or the input signal comprising an instantaneous magnitude signal for inverse conversion to an output analog signal having amplitude, frequency and phase components, comprising a first component comprising a resistive plane, the first component having a first zone and a second zone, the first zone comprising a first set of first electrodes contacting the resistive plane at first defined locations and the second zone comprising a second set of electrodes contacting the resistive plane at second defined locations; the first electrodes comprising a first subset of first electrodes permanently connected to external terminals; and a second subset of first electrodes for connection to external terminals during controlled time periods; the second electrodes comprising a first subset of second electrodes permanently connected to external terminals and a second subset of second electrodes connected to external terminals during controlled time periods; wherein one of the first set of electrodes and second set of electrodes comprises signal injection electrodes and the other of the first set of electrodes and second set of electrodes comprises sensor electrodes; the signal injection electrodes being provided to allow a pattern of bias to be applied to the resistive plane and injecting currents or forcing potential at either the first or second defined locations; the sensor electrodes being provided for sensing a potential on a surface of the resistive plane at the other of the first or second defined locations.

### CROSS-REFERENCE TO RELATED APPLICATIONS

The present application claims the benefit and priority of U.S. Provisional application Ser. No. 60/913,922 filed Apr. 25, 2007, entitled “SIMPLE HARMONIC PROCESSOR,” the entire disclosure of which is hereby incorporated by reference herein.

### BACKGROUND OF THE INVENTION

Modern power electronic converters often rely on vector analysis of harmonic waveforms. For example, FIG. 1 shows a 3 phase motor drive controller using vector control techniques. The block diagram of FIG. 1, which is described in U.S. Pat. No. 6,856,109, includes a 3 phase/2 phase projection which projects the 3 phases of the motor spaced physically at 120° along 2 orthogonal axis which are usually referred to as the d and q axes. This is shown by the vector demodulator in FIG. 1. The vector demodulator takes two vector current inputs from the motor (the third input is not necessary as it can be derived from the other two inputs) and generates two orthogonal outputs.

FIG. 1 also shows that a vector rotator is used for the reverse transformation. The vector rotator rotates a vector by an angle theta. This operation is the coordinate transformation expressing the physical values of the motor in a frame of reference different from the fixed frame. The value of theta is usually time dependent and is calculated. In the simpler case of a brushless DC motor (BLDC) voltage, theta is the angular position of the rotor. In the case of an induction motor, the value of the induction motor slip is taken into account. Thus, the vector rotator implements a 2 phase/3 phase modulation.

These operations require some matrix multiplications with evaluation or tabulation of trigonometric functions at a high speed to ensure adequate bandwidth in the control loop. This is implemented digitally, with high gate count, placing some economical limitations on the widespread use of these techniques.

### SUMMARY OF THE INVENTION

It is an object of the present invention to provide a simple device that can perform the vector rotations and projections and their reciprocal transforms directly on the input analog signals.

In the embodiment described, the device is a resistive planar element. As it will become clear from the following descriptions, the main advantages of the invention are the capability to be integrated in most IC processes, the usage of less silicon area, even with older generation processes, a potentially large analog bandwidth and elimination of the need for high resolution A to D converters.

The invention may have higher error and some distortion and may not be as flexible as digital processors. However, for certain applications, it will provide an improved, simpler and more cost effective solution. Primary targets of the invention are motor drives, although it is believed that other applications could make use of the invention, like lighting ballasts, power factor correction converters and other resonant converters.

Other features and advantages of the present invention will become apparent from the following description of the invention which refers to the accompanying drawings.

### BRIEF DESCRIPTION OF THE DRAWINGS

The invention will now be described in greater detail in the following detailed description with reference to the drawings in which:

FIG. 1 shows a block diagram of a motor drive employing prior art vector transformation techniques that can employ the invention;

FIG. 2 shows a first block diagram of a processor of the invention;

FIG. 3 shows a harmonic processor element of the block diagram of FIG. 2;

FIG. 4 shows a two injector embodiment functioning as a single phase vector analyzer;

FIG. 5 shows a finite element analysis of the equipotential lines of the harmonic processor near the center of the resistive planar element;

FIG. 6 shows a further embodiment with phase rotation;

FIG. 7 shows a four injector embodiment;

FIG. 8 shows further finite element analyses of the equipotential lines at different angles near the planar center;

FIG. 9 shows a simplified four injector embodiment;

FIG. 10 shows an implementation;

FIG. 11 shows details of the embodiment of FIG. 10;

FIG. 12 shows another embodiment;

FIG. 13 shows the embodiment of FIG. 13 with injected currents; and

FIG. 14 shows a further four injector embodiment.

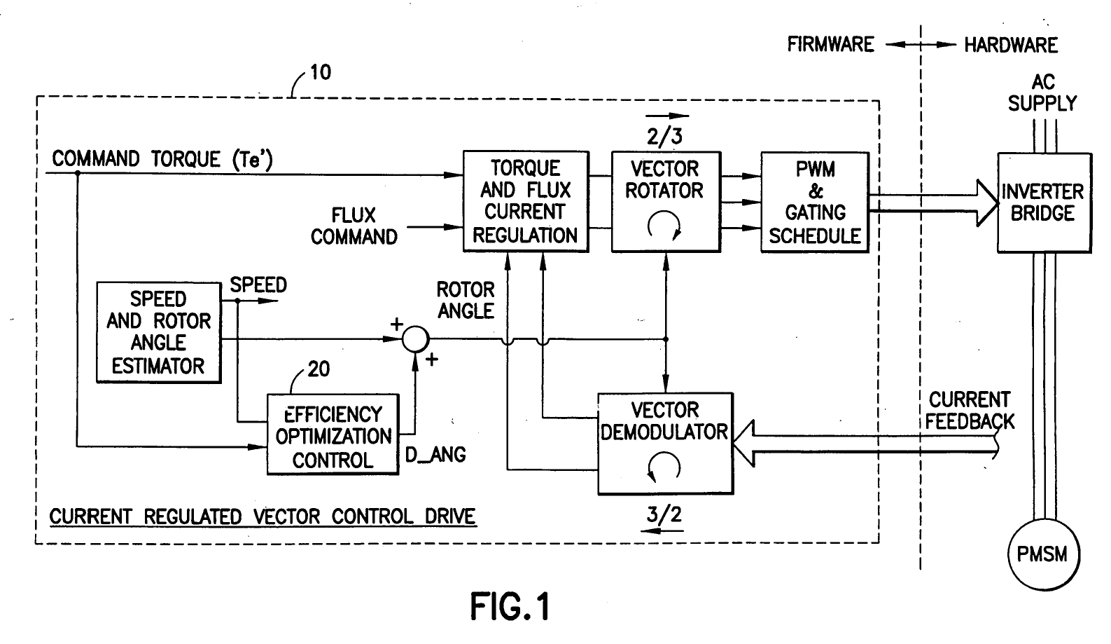

### DETAILED DESCRIPTION

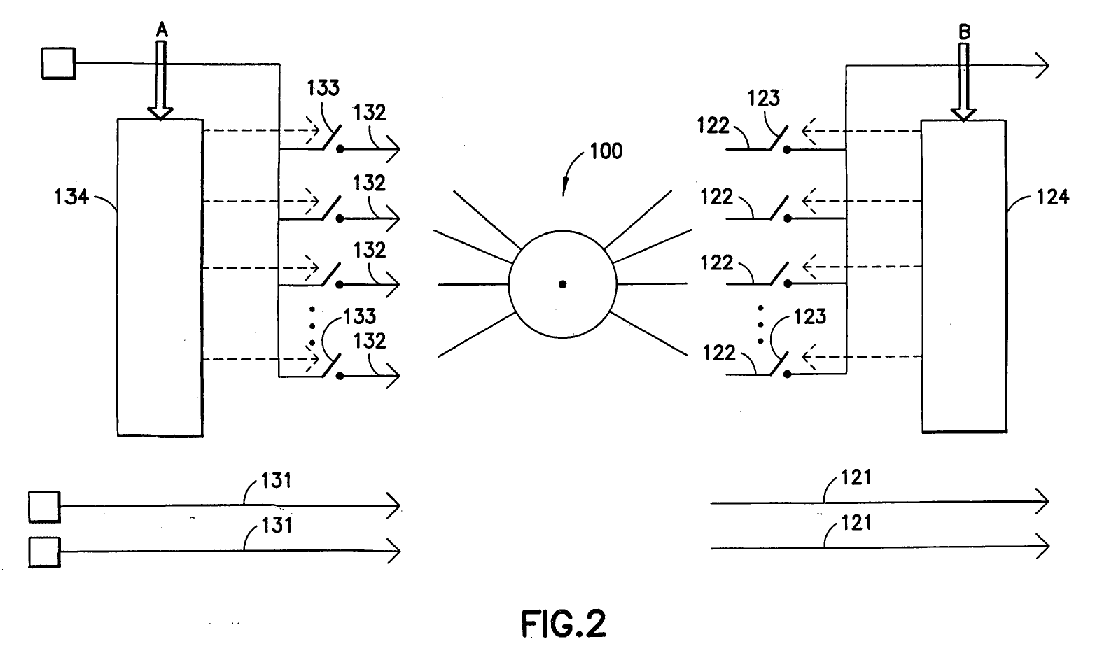

With reference to the drawings, FIG. 2 shows a first embodiment of the harmonic processor according to the present invention.

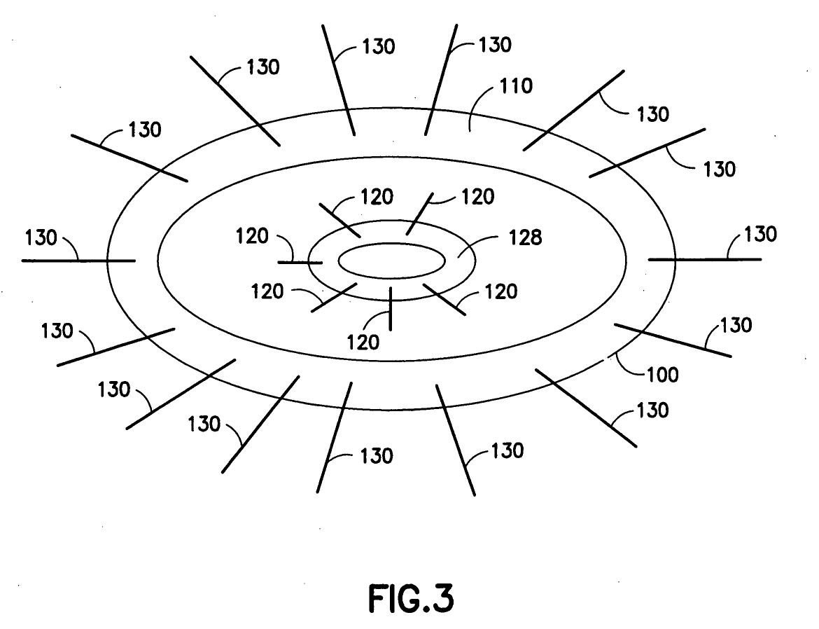

The invention comprises a harmonic processor element 100 preferably comprising a resistive plane. The harmonic processor is shown in detail in FIG. 3. The resistive plane 100 is made of a uniform conductivity layer. This resistive plane comprises at least two distinct zones, a first zone 110 and a second zone 128. In the embodiment described, the first zone is being used as a signal injection zone. The second zone is being used as a signal measurement zone. However, the first zone could be used as the signal measurement zone and the second zone could be used as the injection zone. Which zone is used to inject current and which is used for measurement will depend on the particular transformation being performed, e.g., three vectors to two vectors or two vectors to three vectors. In the embodiment described the first zone 110 is used for signal injection and the second zone for measurement.

The signal injection zone 110 comprises a set of electrodes 130, referred to herein as injectors, contacting the resistive layer at well defined locations. The injectors allow injecting a pattern of bias on the resistive plane by injection of currents or forcing potential at those well defined locations.

A first subset 131 of the injectors (FIG. 2) is permanently connected to external terminals connected to the external circuit to which the harmonic processor is connected, e.g., a motor drive. These injectors 131 are referred to as fixed injectors herein.

A second subset 132 of the injectors, as shown in FIG. 2, is connected to terminals of the external circuit only during controlled periods. These are referred to as rotating injectors. This does not mean that they physically rotate but that they are connected to the external circuit at certain times periodically and in a sequence.

In practice, an analog switch 133 connects each rotating injector 132 to the external circuit during a defined time period and there is provided an addressing device 134 to address any particular analog switch, according to the value of a digital word A.

The signal sensing zone 128 comprises another set of electrodes 120 which allow sensing the potential on the surface of the resistive plane at some other well defined locations. These are referred to herein as sensors.

A first subset of the sensors 121 is permanently connected to some terminals of the external circuit, for example, the motor drive. These are referred to herein as fixed sensors.

A second subset of the sensors 122 are connected to the external circuit only during controlled periods via switches 123. These are referred to herein as rotating sensors.

In practice, there is an analog switch 123 connecting each of the rotating sensors 122 to the addressing device 124 which addresses each analog switch 123 according to the value of a second digital word B. As with the rotating injectors 132, the rotating sensors 122 do not physically rotate, but are connected into the external circuit at a certain time determined by the device 124.

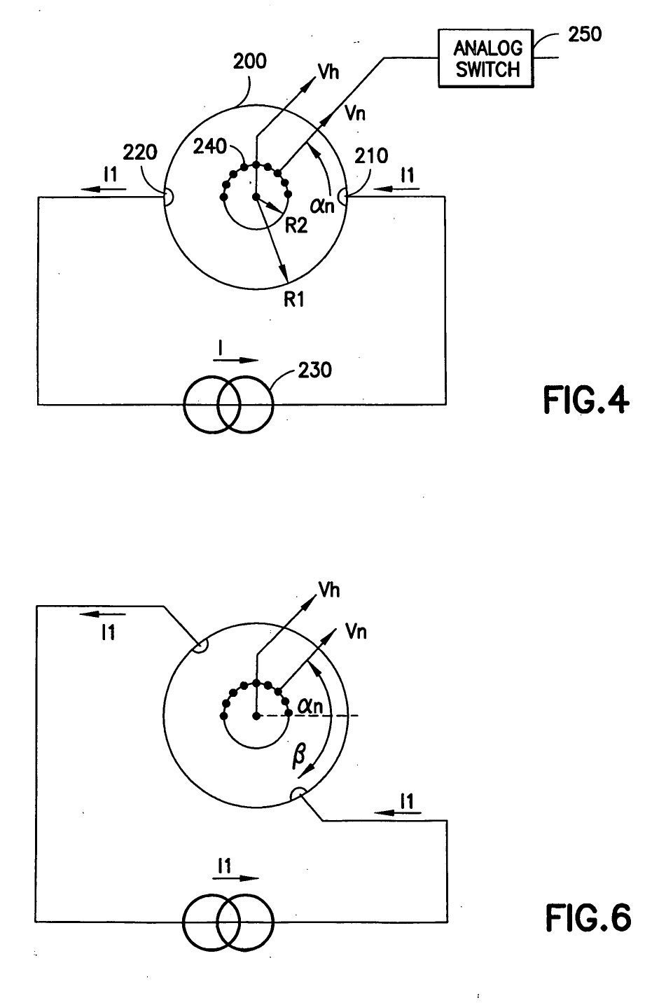

A single phase vector analyzer and rotator will now be described, with reference to FIG. 4.

The device of FIG. 4 is shown as resolving an input vector into its instantaneous magnitude as time progresses. However the device could also be used for the reverse transformation, converting input analog vector magnitude signals into a vectorial current I₁.

In the embodiment shown, circular geometries will be assumed, although a circular geometry is not essential. The resistive plane 200 is a disc of radius R1, centered at the origin O. The injection zone is the concentric circle of radius R1. The sensor zone is the concentric circle of radius R2. R2/R1 is much less than one for good linearity. The resistive plane 200 is a circle of N+ polysilicon layer of typically 150μ in radius. This choice is motivated by good uniformity of the sheet resistance of this layer and its decoupling from the bulk silicon by a dielectric layer.

The large set of injection electrodes in the generalized processor element of FIG. 3 is reduced to a pair of identical electrodes 210, 220 symmetrically located on the periphery of the resistive plane 200.

The exact shape of the two injector electrodes is not critical. In this explanation, it will be assumed that they are each quasi semicircles with a center on the edge of the resistance and a radius of 5μ. The injector electrode can be made of an aluminum to polysilicon ohmic contact. Because only a pair of injectors is used, no addressing circuitry 134 (FIG. 2) is required in this case.

The two injectors 210, 220 are driven by an external current generator 230. It is assumed that the instantaneous value of the forced current is the input variable which can be written as the vector I(t)=I0*sin(ωt) having amplitude 10, frequency w and phase=0. The set of sensing electrodes 240, only some of which are shown in FIG. 4, comprises an assembly of 64 contacts to the resistive plane evenly distributed on a circle of a 50μ radius. The contacts will be of the minimum permitted size to minimize the perturbation on the equipotential lines. An additional contact Vh or homopolar sensor (fixed sensor), is at the origin, at the center of symmetry of the structure.

Each rotating sensor 240 is connected by an analog switch 250, which is shown, to a circular bus, and then to the output of the device. Only one connection to a rotating sensor is shown in FIG. 4 for clarity.

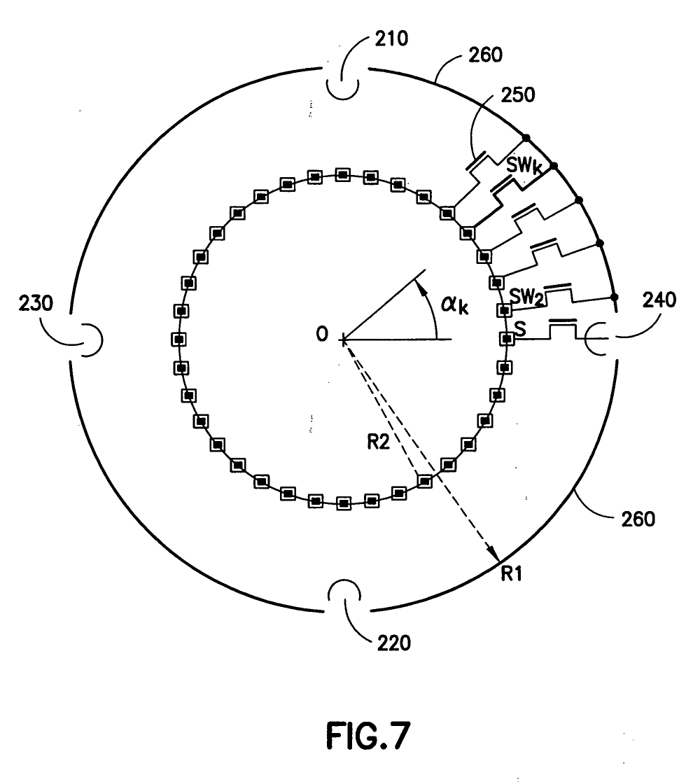

Each analog switch 250 comprises a transistor, for example, an NMOS transistor. The analog switches 250 are shown in FIG. 7, for a different embodiment, as a set of NMOS transistors. Also shown in FIG. 7 is the circular bus 260.

The gate of each switch 250 is connected to the output of a 1 to n binary decoder contained in the device 124 of FIG. 2. At any given time there is exactly one single analog switch closed. For example, inputting the digital word, 001001 will set the 9^{th} analog switch to be closed. The voltage on the output is equal to the potential on the circle of radius R2 at an angle 9/64 from the reference point. The homopolar signal Vh is also permanently available on a second output terminal. This is a fixed sensor.

With reference to FIG. 4, a DC current I₁ is injected from the first injector 210 to the second injector 220. The potential at any point of the resistance is the solution of Poisson's equation of the form ΔV=RsJ.

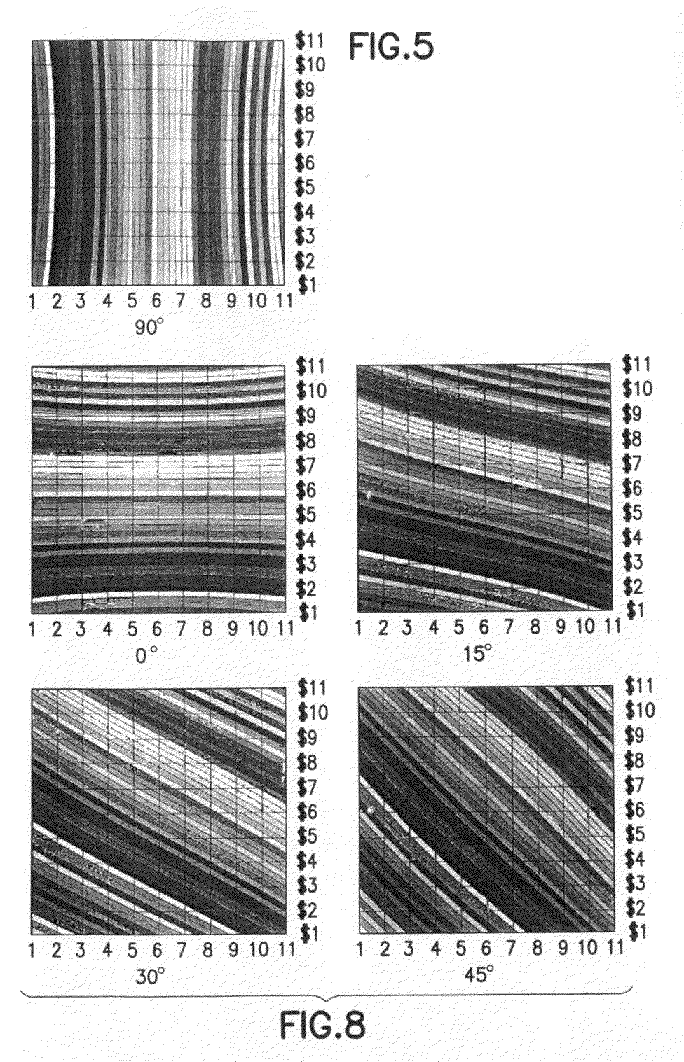

In this equation, J is the density of the current injected and Rs is the sheet resistance of the resistive plane. With the geometry described, it can be shown that equipotential lines and the current lines will be a family of orthogonal circles. If one looks only to the potential in the vicinity of the center of symmetry, one can show that the electric field is fairly uniform. This is visible in the result of the finite element analysis as shown in FIG. 5 and in FIG. 8.

Near the center, the equipotential lines become flat. The radius R2 of the inner sensor circle is chosen to be small in comparison to the resistive plane such that the assumption of a constant electric field is valid.

Consider the potential on a sensor S₁, located at (p,α) in a polar coordinate system and (X₁,Y₁) in rectangular coordinates where X₁=p cos(α₁) and Y₁=p sin(α₁).

By symmetry, V(0)=0.

V(S₁)=V(0)+∫(Ex·dx+Ey·dy) from (0,0) to (X₁,Y₁).

Since the integration is independent from the path, integration can be performed first along the X axis and then on the Y axis. This results in an equation:

V(S₁)=∫_{(0->X)}(Ex·dx)+∫_{(0->Y)}(Ey·dy)=Ex*p cos(α₁).

Assuming that the resistance is linear for a given p, it can be established that

V(S₁)=I₁K·cos(α₁).

This equation expresses the sensitivity of the node k to the current I₁.

If a second sensing electrode S₂ located at (p,α₂), is considered, it will be determined that

V(S₂)=I₁K·cos(α₂).

The same system can be considered but with a pair of injectors rotated by a phase angle β from the embodiment of FIG. 4. This is shown in FIG. 6. In this particular figure, the injectors are rotated by an angle B. From this, it can be determined that

V(Sₖ)=I₂K·cos(αₖ−β).

The above can be generalized. The potential on sensor number k resulting from forcing the current Ij in injectors number j can be written as

V(k,j)=KI·(Iⱼ·cos(αₖ−βj)).

By applying the superposition theorem, it can be determined that the potential pattern resulting from more than one pair of injectors is determined by the following equation

V(k)=K·Σⱼ(Iⱼ·cos(αₖ−βj)).

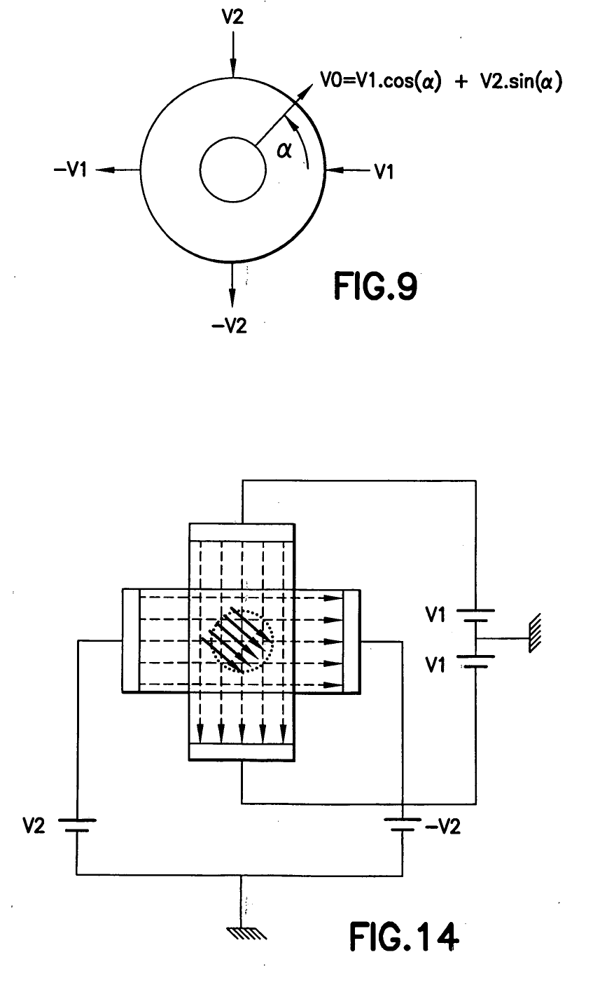

FIG. 9 shows another phase analyzer having four injectors for injecting two currents. In FIG. 9, V1 and V2 are two current sources in quadrature, i.e., having a phase angle of 90° between them. For example,

I₁=I*cos wt and I₂=I*sin wt.

If the sensor is rotating at the same rotational frequency, α=wt, then the two rotating sensors should give the two components Vd and Vs of the input signal, that is,

V1 cos α and V2 sin α.

FIG. 7 shows a more detailed view of the embodiment of FIG. 9.

FIG. 8 shows the finite element analysis of the quasi uniform electric field at the center at various angular orientations.

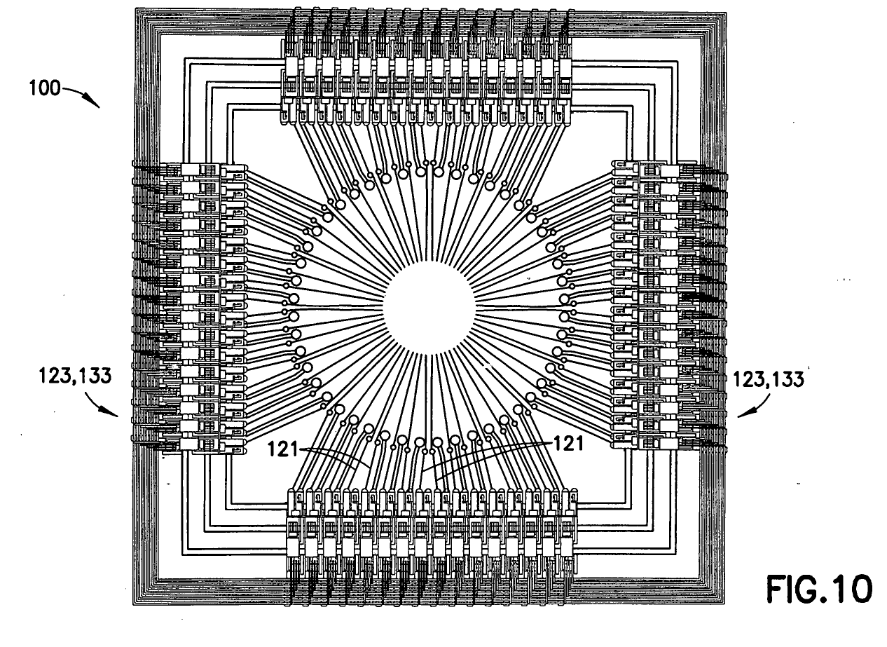

FIG. 10 shows how an embodiment of the harmonic processor may be arranged on an integrated circuit.

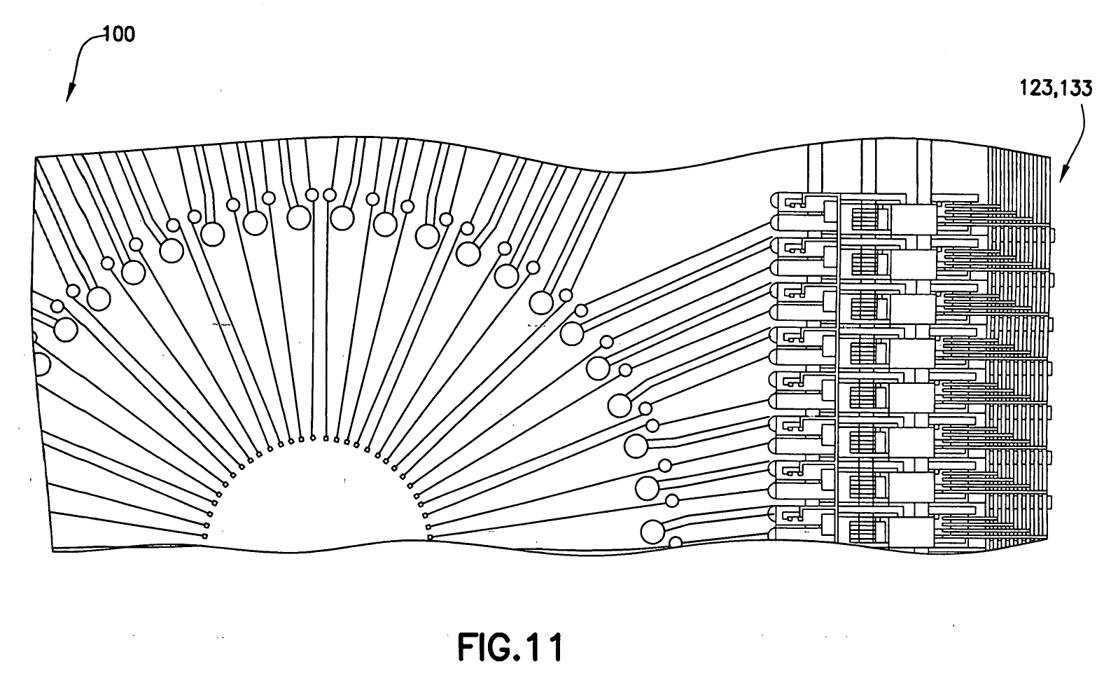

FIG. 11 shows details of the circuit of FIG. 10. Both figures show the sensors, injectors and switches.

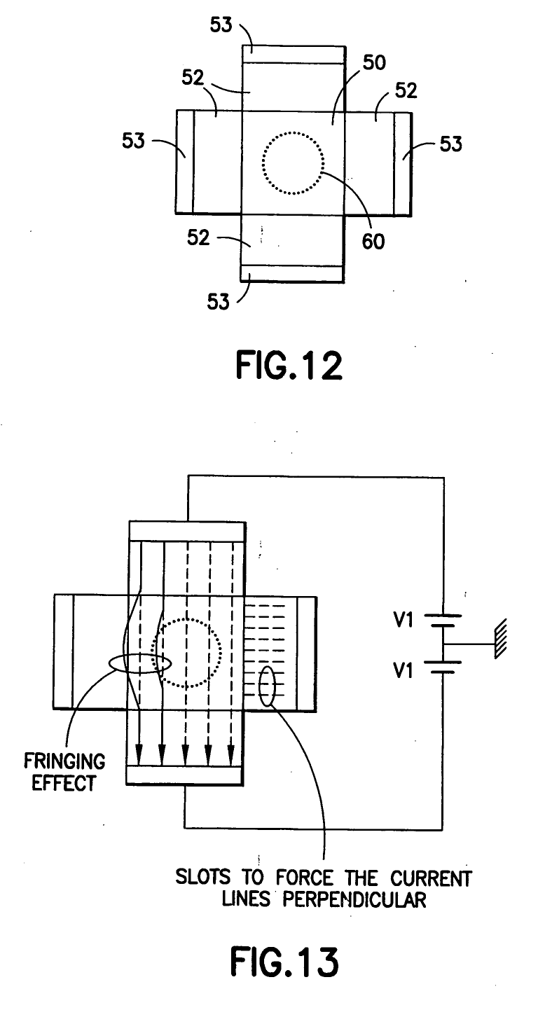

FIGS. 12-14 show a further embodiment, showing that the geometry need not be circular. In FIG. 13, the processor comprises a resistor having a central area 50, that has the shape of a regular polygon of n sides, in this case a square, n=4. There are two identical legs 52 forming a star configuration.

The four legs 52 and the central square 50 are made of a uniform thickness and resistivity material. Each leg is terminated by some highly conductive material 53 to create a good ohmic contact. The proportion suggested between the legs and the square is not critical, but going to extreme values may affect the linearity of the system. Finally, there is a circular shaped array of contacts 60 symmetrically and evenly distributed around the center of symmetry of the resistance. Each of those contacts is connected to an analog multiplexer, not shown, but as shown in FIG. 2 by 124.

If a symmetrical voltage is applied on 2 opposite contacts as shown in FIG. 13, a current will flow between those 2 contacts. Because of the symmetry of the shape, one can see that the current lines inside the resistor will be quasi straight lines between the 2 contacts, except for some fringing effect at the intersection with the other leg, as shown in FIG. 13.

The electric field will be almost uniform from top contact to bottom contact, and it will have a vertical direction. If the voltage is applied between the right and left contact, there will be a uniform horizontal electric field.

If the four terminals are connected to V1 and V2, as shown in FIG. 14, the new field pattern will be the addition of the 2 field patterns previously obtained. This results from the linearity of the Laplace equation (assuming the resistor media is linear and homogenous).

It can be shown that if we stay close enough to the center of symmetry of the structure, the resulting current lines (and electric field) will be the vectorial sum of V1 and V2, as shown in FIG. 14. Forcing V1 and V2 to be of the form

V1=A·sin(θ)

V2=A·cos(θ)

will result in an electric field rotated by an angle (θ). In this example, the invention is performing as a Cartesian to polar coordinate converter. The set of equipotential lines of FIG. 8 and FIG. 5, have been determined by solving Laplace's equation by a simple numerical method, at angles of respectively (0, 15, 30, 45 and 90°), as shown.

The harmonic processor described above combines a set of input voltages to generate a rotating electric field. Assuming perfect linearity, the electric Ex and Ey components can be expressed as:

Ex=V1*cos(θ)+V2*sin(θ)

Ey=V1*cos(θ+Π/2)+V2*sin(θ+Π/2)

FIG. 9 shows the case of a 3 phase voltage input u, v, w, for example, motor currents. Thus, the input voltages u, v, was sourced by V1 and V2 are transformed into the vector V0 having the two components V1 cos α and V2 sin α, a 3/2 transformation.

The circular shaped array of contacts is symmetrically and evenly distributed around the center of symmetry of the resistance. Each of those contacts is connected to an analog multiplexer.

It results from the linearity of the media and of Laplace's equation if two sinewaves in quadrature are forced on V1/V2, a sensor point having polar coordinates r, a will see a sinewave of frequency α.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A harmonic processor receiving an input signal and providing an output signal, the input signal comprising a first analog signal having amplitude, frequency and phase components and being converted to an instantaneous magnitude output signal, or the input signal comprising an instantaneous magnitude signal for inverse conversion to an output analog signal having amplitude, frequency and phase components, comprising:
a first component comprising a resistive plane, the first component having a first zone and a second zone, the first zone comprising a first set of first electrodes contacting the resistive plane at first defined locations and the second zone comprising a second set of electrodes contacting the resistive plane at second defined locations;
said first electrodes comprising a first subset of first electrodes permanently connected to external terminals; and a second subset of first electrodes for connection to external terminals during controlled time periods;
said second electrodes comprising a first subset of second electrodes permanently connected to external terminals and a second subset of second electrodes connected to external terminals during controlled time periods;
wherein one of the first set of electrodes and second set of electrodes comprises signal injection electrodes and the other of the first set of electrodes and second set of electrodes comprises sensor electrodes;
the signal injection electrodes being provided to allow a pattern of bias to be applied to the resistive plane and injecting currents or forcing potential at either the first or second defined locations;
the sensor electrodes being provided for sensing a potential on a surface of the resistive plane at the other of the first or second defined locations.

2. The harmonic processor of claim 1, further comprising a first analog switching device comprising a plurality of analog switches each connected to respective electrodes of the second subset of first electrodes, and further comprising an address device for addressing each of the switches; further comprising a second switching device comprising a plurality of switches each connected to respective electrodes of the second subset of second electrodes and further comprising an address device for addressing each of the second electrodes of the second subset of second electrodes.

3. The harmonic processor of claim 1, wherein the resistive plane has a uniform conductivity.

4. The harmonic processor of claim 1, wherein
the first electrodes are at a distance R1, from a center of the resistive plane and the second electrodes are at a distance R2, where R1>R2.

5. The harmonic processor of claim 4, wherein the resistive plane comprises a circular disk.

6. The harmonic processor of claim 1, wherein the phase component is determined by spacing the first electrodes at a fixed angle with respect to a reference location for the second electrodes.

7. The harmonic processor of claim 1, wherein the resistive plane has a star configuration.

8. The harmonic processor of claim 1, wherein there are two signal injection electrodes for receiving a vector analog input signal having amplitude, frequency and phase components and wherein the sensor electrodes are connected to an external circuit at a frequency equal to the frequency of the analog input signal for producing instantaneous vector magnitude signals.

9. The harmonic processor of claim 1, wherein there are four signal injection electrodes arranged in pairs at 90° for receiving two quadrature related vector analog input signals having amplitude, frequency and phase components and the sensor electrodes are connected to an external circuit at a frequency equal to the frequency of the analog input signals for producing vector magnitude signals.
